(19) United States
(12) Patent Application Publication
(10) Pub. No.: US 2014/0062849 A1
(43) Pub. Date: Mar. 6, 2014

(54) CMOS-COMPATIBLE DISPLAY SYSTEM AND METHOD

(71) Applicant: TAGNETICS, INC., Troy, OH (US)

(72) Inventor: Kenneth W. Kayser, Salem, VA (US)

(73) Assignee: TAGNETICS, INC., Troy, OH (US)

(21) Appl. No.: 13/833,057

(22) Filed: Mar. 15, 2013

Related U.S. Application Data
(60) Provisional application No. 61/696,998, filed on Sep. 5, 2012.

(51) Int. Cl. G09G 3/34; H01L 33/00

(52) U.S. Cl. CPC G09G 3/344; H01L 33/0004
USPC 345/107; 438/23

(57) ABSTRACT

An electrical control system for controlling the electrical voltage applied to each of multiple pixel electrodes on one side of an electrophoretic display comprises (1) a substrate having a plurality of spaced parallel aluminum conductors on one side of the substrate; (2) a thin oxide layer on spaced pixel regions of each of the aluminum conductors to form a gate insulator over each of the spaced pixel regions; (3) a field-effect transistor (FET) formed on the thin oxide layer in each of the spaced pixel regions, the FET having a source terminal, a drain terminal, and a gate connected to the aluminum conductor on which the FET is formed; and (4) a CMOS controller connected directly to each of the aluminum conductors and adapted to supply gate control signals for the FETs. The controller supplies a separate gate control signal for each of the aluminum conductors.

### CROSS REFERENCE TO RELATED APPLICATIONS

This application claims priority to provisional U.S. Application No. 61/696,998, filed Sep. 5, 2012, which is hereby incorporated by reference herein in its entirety.

### FIELD OF THE INVENTION

The present disclosure generally relates to displays having a matrix of pixels, each of which includes a field effect transistor (“FET”) for controlling the characteristics of the individual pixels.

### BACKGROUND

Considerable work has been done on a variety of different displays, including electrophoretic displays such as those utilizing “E Ink” or “E Paper,” in which the controllable display elements or “pixels” can be in either a dot matrix format or a segmented format. In either case, a separate FET is typically utilized to control each display element.

### SUMMARY

In accordance with one embodiment, a method of forming an electrical control system for controlling the electrical voltage applied to each of multiple pixel electrodes on one side of an electrophoretic display comprises (1) providing a substrate having a plurality of spaced parallel aluminum conductors on one side of the substrate; (2) forming a thin oxide layer on spaced pixel regions of each of said aluminum conductors to form a gate insulator over each of the spaced pixel regions; (3) forming a field-effect transistor (FET) on the thin oxide layer in each of the spaced pixel regions, the FET having a source terminal, a drain terminal, and a gate connected to the aluminum conductor on which the FET is formed; and (4) a CMOS controller connected directly to each of the aluminum conductors and adapted to supply gate control signals for the FETs. The controller supplies a separate gate control signal for each of the aluminum conductors. Each FET has a threshold voltage that is CMOS compatible.

In one implementation, the FET has a threshold voltage of less than 3 volts. The thin oxide layers in the pixel regions along each aluminum conductor are formed by oxidizing the surface of the aluminum conductor, such as by anodizing or annealing the aluminum conductor. The oxide layer has a thickness of less than one micron, preferably less than 0.5 micron. This permits the FET to be made to have a threshold gate voltage of only a few volts, e.g., less than 3 volts and preferably in the range from about 1 to about 2 volts, so that the threshold gate voltage is CMOS compatible. This low threshold gate voltage of the FET can avoid the need for a driver circuit for the gate lines which in turn reduces the cost of the display.

Another embodiment provides an electrophoretic display comprising a substrate having a plurality of spaced parallel aluminum conductors on one side of the substrate; a thin oxide layer on spaced pixel regions of each of the aluminum conductors to form a gate insulator over each of the spaced pixel regions; a field-effect transistor (FET) on the thin oxide layer in each of the spaced pixel regions, the FET having a source terminal, a drain terminal, and a gate connected to the aluminum conductor on which the FET is formed; and a CMOS controller adapted to supply gate control signals for the FETs directly to the gates of the FETs.

The foregoing and additional aspects and embodiments of the present invention will be apparent to those of ordinary skill in the art in view of the detailed description of various embodiments and/or aspects, which is made with reference to the drawings, a brief description of which is provided next.

### BRIEF DESCRIPTION OF DRAWINGS

The foregoing and other advantages of the invention will become apparent upon reading the following detailed description and upon reference to the drawings.

FIG. 1 is an exploded perspective of a portion of an electrophoretic display, and a schematic diagram of the electrical control system associated with the display.

FIG. 2 is an enlarged diagrammatic side elevation of one of the FETs included in the electrical schematic portion of FIG. 1, along with the adjacent portion of the electrophoretic display.

FIGS. 3A-3C are diagrammatic plan views of successive stages of forming the FET of FIG. 2 at one of the pixel locations spaced along the length of one of the column lines shown in FIGS. 1 and 2.

FIG. 4 is an electrical schematic of the power supply included in FIG. 1, and the circuitry associated with the power supply and the controller included in FIG. 1.

FIG. 5 is an enlarged diagrammatic side elevation of a modified FET for use in the electrical schematic portion of FIG. 1, along with the adjacent portion of the electrophoretic display.

FIGS. 6A-6C are diagrammatic plan views of successive stages of forming the FET of FIG. 5 at one of the pixel locations spaced along the length of one of the column lines shown in FIGS. 1 and 2.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

### DETAILED DESCRIPTION

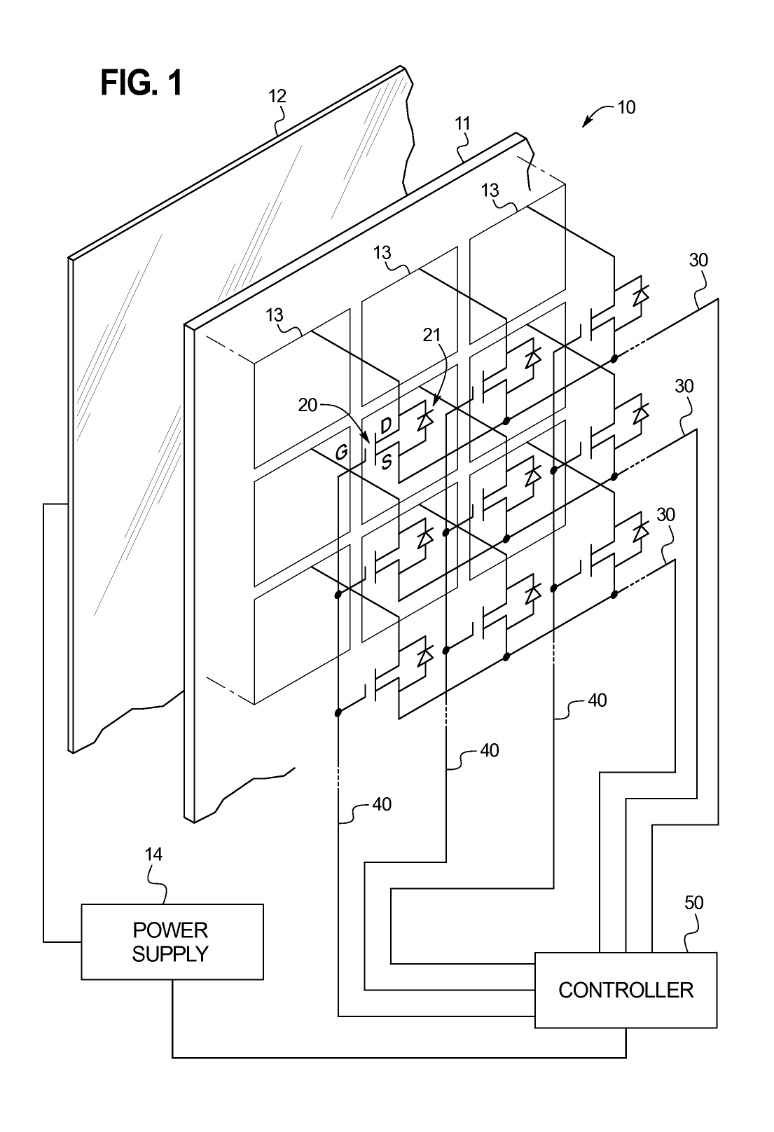

FIG. 1 illustrates an electrophoretic display 10 that includes a panel 11 of electrophoretic material having a single transparent electrode 12 on one side of the panel and multiple pixel electrodes 13 on the other side of the panel 11. The pixels defined by the pixel electrodes 13 form multiple controllable display elements, which in the illustrated example are arranged in a dot matrix format that includes multiple rows and columns of the pixel electrodes 13. The rows and columns form a conventional x-y matrix of pixels in which each individual pixel can be independently controlled so that the overall matrix of pixels displays desired images. The size of the display can vary over a wide range depending upon the application. For example, a small display suitable for use as a shelf tag in retail store can have use a matrix as small as 1″×1.5″ containing 10 rows and 15 columns of pixels. Large displays can have hundreds of rows and hundreds of columns.

Some or all of the pixel electrodes 13 can be in “segmented” rather than “dot matrix” form. In a segmented display, pixels are arranged so that alphanumeric characters can be formed by selectively activating various combinations of the segmented pixels. The segments can be uniform in size and shape, or they can be non-uniform in size and shape relative to one another. In a dot matrix display, all the pixels have a uniform size and shape and are typically arranged in a matrix of M×N rows and columns. The pixels of the display 10 can be all segmented, all dot-matrix, or a combination of segmented and dot matrix forms. For electronic shelf tags, certain portions of the display can be static, such as a “SALE” segment that can just be turned on or off, while other portions can be controllably varied to display different images. In the static portions of the display 10, the pixel electrodes 13 can be shaped and sized to conform to the static image to be displayed. For example, if the word SALE will always appear in the same location in a static portion on the display 10, four pixel electrodes 13, each shaped to form one of the letters S, A, L or E, can be disposed in that portion of the display. Each pixel electrode can be controlled by a separate drive transistor, or a single drive transistor may control all four pixel electrodes.

In the illustrative example, the electrophoretic panel 11 can be made of commercially available materials such as “E Ink” or “E Paper” panels. Electrophoretic panels are bistable and require power only when refreshing the image data, as is well known. The pixels of the display are defined by the pixel electrodes 13 on the rear side of the panel 10, and the single electrode 12 on the front side of the panel 11 is common to all the pixels. The electrode 12 is made of a transparent material to permit the display formed by the pixel matrix to be viewed from the front side of the panel. Depending upon the electrophoretic material used in the panel 11, the display may be black and white, shades of gray or color.

The common electrode 12 is connected to a power supply 14 that is controlled to supply the common electrode with either a positive or negative voltage, e.g., +15 volts or −12 volts. When the negative voltage is supplied to the common electrode 12, the entire display is “erased” by turning all the pixels black. With electrophoretic materials, a black pixel is non-reflective. When the positive voltage is supplied to the common electrode 12, the individual pixels can be controlled by the signals supplied to individual FETs 20 connected to the respective pixel electrodes 13. Each FET 20 has a source S, a drain D and a gate G, and a diode 21 between the source and drain. The diode 21 permits the associated pixel to be turned off when a negative voltage is applied to the common electrode 12, regardless of whether the associated FET 20 is on or off. As will be described in detail below, the diode 21 is preferably formed as an integral part of the FET 20.

Each of the FETs 20 has its drain D connected to one of the pixel electrodes 13, and its source S is connected to one of multiple row lines 30. Each row line 30 is common to all the FETs connected to the pixel electrodes 13 in a given row. Each of the FETs 20 has its gate G connected to one of multiple column lines 40, each of which is common to all the FETs connected to the pixel electrodes 13 in a given column. In the illustrated embodiment, the signals supplied to both the row lines 30 and the column lines 40 are either 3 volts or zero volts, and the combination of these two signals at any given FET determines whether that FET is turned on or off. Specifically, if the gate signal is 0 volts, the FET is off regardless of whether the source voltage is 0 or 3 volts. If the gate voltage is 3 volts, the FET is turned on if the source voltage is 0 volts, and the FET is turned off if the source voltage is 3 volts.

The pixel electrodes 13 actually define the individual “pixel” areas of the electrophoretic material. These pixel areas can form a dot matrix display where the displayed image is formed by a multiplicity of dots arranged in an x-y matrix such as rows and columns of dots, and/or a segmented display where the displayed image is formed by one or more segments defined by the pixel electrodes. Each of the pixel electrodes 13 is individually driven to be black or white (absorbing or reflecting) whenever a positive voltage is applied to the common electrode 12. A controller 50 receives digital data indicative of an image to be displayed on the electrophoretic panel 11, and sends corresponding signals to the row lines 30 and column lines 40 to successively drive the pixel electrodes 13 to display the desired image. The multiplicity of pixel electrodes 13 in the display panel 11 thus comprise a display array (“display screen”) adapted to dynamically display images according to the input digital data received by the controller 50. The display screen can display, for example, shelf tag information contained in a stream of data received by the controller 50. The controller 50 is operatively coupled to or includes a memory that includes non-transitory, machine-readable instructions corresponding to a voltage prediction module, which can be embodied as firmware or software.

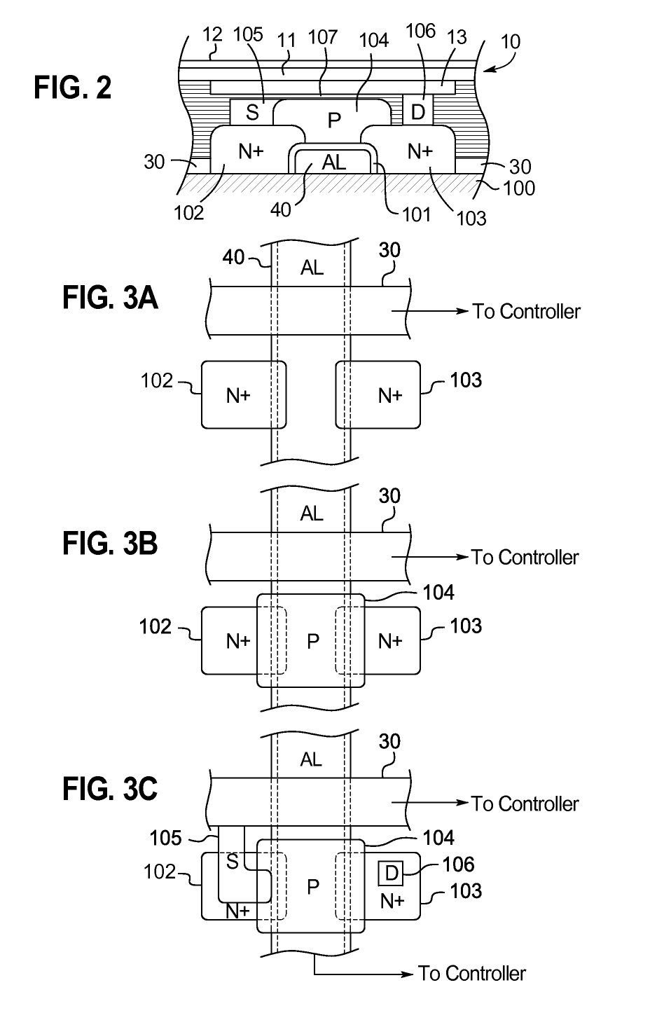

FIGS. 2 and 3A-3C illustrates an example of a FET 20 that can be used in the display of FIG. 1 and formed by printing on the same substrate 100 (e.g., a printed circuit board) on which the row lines 30 and the column lines 40 are formed to define a series of parallel rows and a series of parallel columns, respectively. A FET is printed directly onto a portion of each row line 30 between each pair of adjacent column lines 40. Each FET corresponds to a unique pixel location.

The row lines 40 are preferably made of aluminum, e.g., as a pattern on a printed circuit board (PCB), so that the conductors 40 can be oxidized (e.g., by anodizing or annealing) to form a thin oxide layer 101 on the top surface and side edges of each conductor 40. This oxide layer 101 has a thickness of less than a micron, preferably less than 0.5 micron, and most preferably only a few tenths of a micron (e.g., 0.3 micron), so that each FET has a threshold gate voltage of less than 3 volts, preferably in the range from about 1 to about 2 volts, which is CMOS compatible. The row lines 30 can be printed over the column lines 40, as described in more detail below in connection with FIGS. 3A-3C.

After the conductors 40 have been oxidized, two regions 102 and 103 of n-type material are printed on the substrate 100 along opposite edges of, and slightly overlapping, the oxidized aluminum column line 40 at each pixel location. Next, a layer 104 of a p-type material is printed on the top surface of the oxide layer 101 in the space between the two n-type regions 102 and 103 and overlapping adjacent portions of the n-type regions (see FIG. 3B). A source terminal 105 is then printed on top of each n-type region 102, and the row lines 30 are printed as part of this same operation. As can be seen in FIG. 3C, the source terminal 105 also contacts an adjacent portion of the p-type material 104, thus shorting the n-type region 102 and the p-type material 104 (see FIGS. 2 and 3C). A drain terminal 106 is printed on top of each n-type region 103.

The drain terminal 106 printed on the n-type region 103 is spaced from the p-type material 104 (see FIGS. 2 and 3C). Thus, the p-n junction between the p-type material 104 and the n-type material in region 103 forms a p-n diode between the source and drain of the FET. A dielectric material 107 may be printed over the top surfaces of everything except the drain terminal 106, as can be seen in FIG. 2. Then a pixel electrode 13 is printed over the entire FET, in electrical contact with the drain terminal 106. The drain terminal 106 does not intersect or contact the column line 40.

The electrophoretic panel 11 is disposed over the entire array of pixel electrodes 13, as can be seen in FIG. 1. One side of the panel 11 engages the pixel electrodes 13, and the other side of the panel engages and is covered by the transparent common electrode 12. As described above, the common electrode 12 is connected to the power supply 14, which selects the voltage applied to the electrode 12 according to one or more control signals produced by the controller 50.

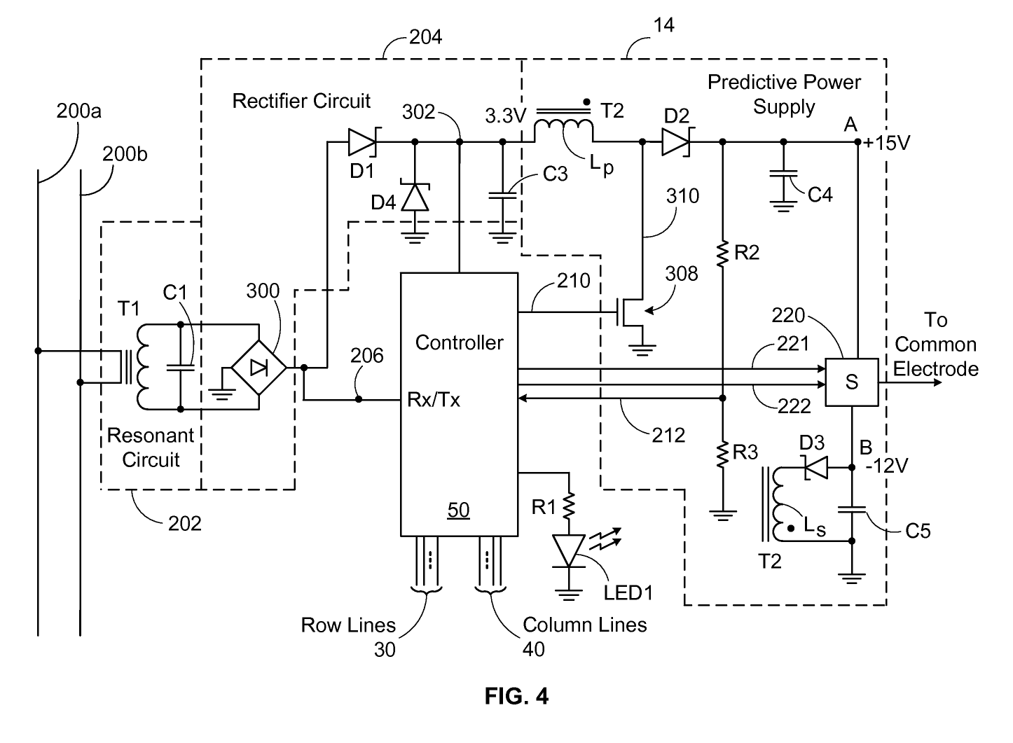

FIG. 4 is a schematic diagram of the power supply 14 that is connected to the common electrode 12, the controller 50, and associated circuitry. A resonant circuit 202 is connected to two conductor rails 200a, 200b, which can extend along the edge of a shelf in shelf tag applications. Electrical current is supplied to the rails 200a, 200b from a remote power source. The resonant circuit 202 includes a coil T1 that inductively couples power and information signals from the rails 200a, 200b, and provides those signals to a diode bridge 300 in a rectifier circuit 204. A capacitor C1 is connected across the coil T1.

The output of the bridge 300 is supplied via diode D1 and line 302 to a power input of the controller 50. The voltage level at node 302 is typically 3.3 volts DC, which is suitable for powering the controller 50. The output of the bridge 300 is also supplied via line 206 to the Rx/Tx input of the controller 50. Using an impedance modulation scheme, information signals coupled to the coil T1 from the rails 200a and 200b are converted to corresponding voltage or TTL signals which are interpreted by the controller 50 and converted into corresponding data.

The node 302 is also connected to one end of the primary winding Lp of a transformer T2 in the power supply 14. The other end of the winding Lp is connected via diode D2 to node A, to provide a positive voltage (e.g., +15V) for application to the common electrode 12 of the electrophoretic display. The secondary winding Ls of the transformer T2 has one end connected via the diode D3 to node B, to provide a negative voltage (e.g., −12V) for application to the common electrode 12. The other end of the winding T2 is connected to ground and capacitor C5 that has its other side connected to node B.

When the FET 308 is on, energy builds up in the primary winding Lp, which is closely coupled to the secondary winding Ls. When the FET 308 is turned off, the voltage across both windings Lp and Ls ramps up and charges the respective capacitors C4 and C5, until the corresponding diodes D2 and D3 are no longer forward biased. The charge on the capacitor C4 is the voltage level at the node A, and the charge on the capacitor C5 is the voltage level at the node B. The voltage levels at nodes A and B are the two voltages available for connection to the common electrode 12 of the electrophoretic panel 10.

A switching module 220 determines which of the two voltages (node A or node B) is connected to the common electrode 12 of the electrophoretic panel 10. In the illustrative example in FIG. 4, node A supplies a positive voltage of +15 volts, and node B supplies a negative voltage of −12 volts. The switching module is controlled by a pair of control signals produced by the controller 50 on output lines 221 and 222, which control whether the positive or negative voltage is connected to the common electrode 12.

To enable the controller 50 to monitor the voltage at node A, a voltage divider is formed by a pair of resistors R2 and R3 connected to ground from a point between the diode D2 and the node A, and a line 212 supplies the voltage level between the two resistors to an input of the controller 50. The controller 50 uses the input signal from line 212 to generate a control signal on an output line 210 connected to the gate of a FET 308, which in turn controls the voltage levels at both nodes A and B. By monitoring the voltage on line 212, which is a function of the voltage drop across the electrophoretic panel 10, the controller 50 tracks the aging of the electrophoretic panel 10, and compensates for that aging by adjusting the control signals on lines 221 and 222. For example, in one implementation, the control signal produced on line 221 or 222 is a series of short pulses, which turns on the FET 308. By adjusting the pulse width and/or the number of pulses, the on time of the FET 308 can be adjusted to achieve the desired voltage levels at nodes A and B, thereby compensating for degradation of the electrophoretic panel 10 and associated components due to aging. The controller 50 can also determine when the panel 10 has degraded to a point where it needs to be replaced.

Specifically, the controller 50 controls both the number and width of the pulses supplied to the gate of the FET 308, which in turn controls the voltage levels at nodes A and B. The controller 50 continually compares the voltage on line 212, which corresponds to the actual voltage at node A, with a desired voltage for the current display. The desired voltages for different display patterns or images (which require different amounts of energy) are stored in the memory associated with the controller 50, along with the initial number and width of the pulses to be supplied by the controller to achieve those voltages when the display is initially put into operation. Then each time the displayed image is changed or refreshed, the actual voltage on line 212 is compared with the desired voltage, and any adjustments needed to achieve the desired voltage are made in the number and width of the pulses supplied by the controller 50 to the FET 308. Images that remain unchanged for prolonged periods are typically refreshed at fixed time intervals. These comparisons and adjustments are continued until the comparisons indicate that the display needs to be replaced.

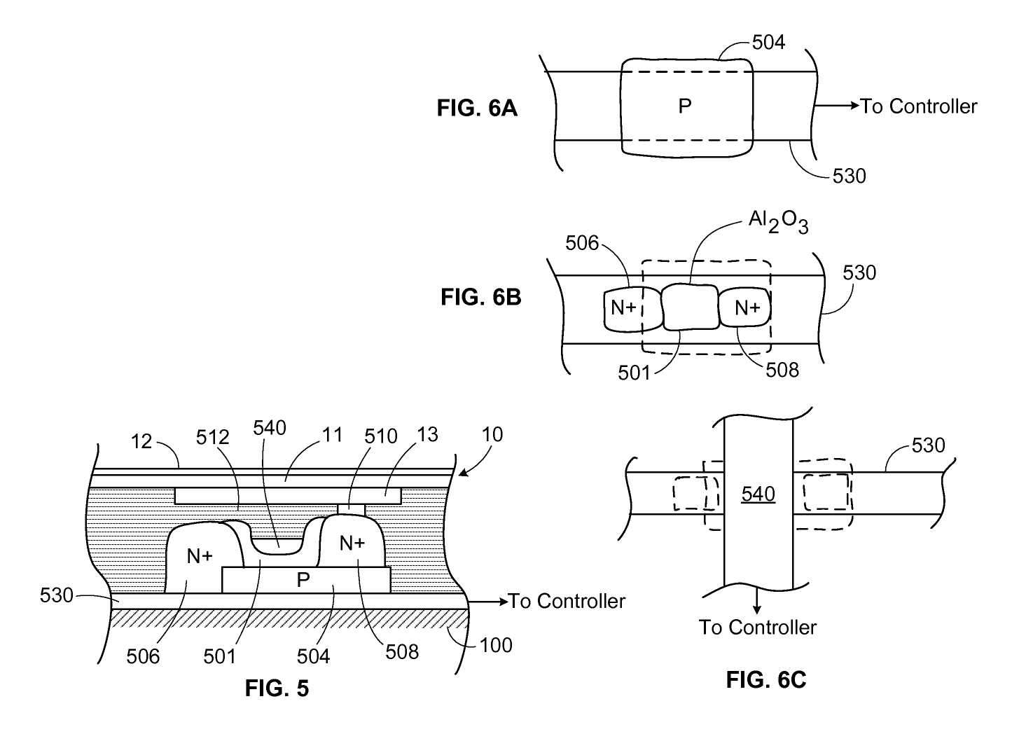

FIGS. 5 and 6A-6C illustrate an alternative construction of an n-type FET. A number of spaced parallel column lines 540 are printed on the substrate 100, for direct connection to the controller 50. An inkjet printer is used to print a p-type layer 504 directly onto uniformly spaced regions of the column lines 540 (see FIG. 6A), and then a region 506 of n-type material is printed next to each region of p-type material 504 (see FIG. 6B). The p-n junction between the p-type material 504 and the n-type material in region 506 forms a p-n diode between the source and drain of the FET. Another region 508 of n-type material is printed directly onto the p-type layer 504 such that no part of the n-type material in any region 508 contacts the column line 540 (see FIG. 6B).

A thin oxide layer 501 is formed between the two regions 506 and 508 of n-type material to form a gate insulator between the two semiconductor bulk materials (see FIG. 6B). A row line conductor 530 is disposed over the oxide layer 501 and is connected directly to the controller 50 (see FIG. 6C). A drain terminal 510 is printed onto the n-type material 508, and a pixel electrode 13 is printed over the entire FET, in electrical contact with the drain terminal 106. A dielectric material 512 covers the top surfaces of everything except the drain terminal 510 and the pixel electrode 13, as can be seen in FIG. 5. A pixel electrode 13 is connected to the drain terminal 506, and the electrophoretic panel 11 is disposed over the pixel electrode 13. The source terminal is provided by the column line 540, which is in contact with both the n-type region 506 and the p-type region 504, thus shorting the n-type region 102 and the p-type material 104.

While particular embodiments and applications of the present invention have been illustrated and described, it is to be understood that the invention is not limited to the precise construction and compositions disclosed herein and that various modifications, changes, and variations can be apparent from the foregoing descriptions without departing from the spirit and scope of the invention as defined in the appended claims.

1. A method of forming an electrical control system for controlling the electrical voltage applied to each of multiple pixel electrodes on one side of an electrophoretic display, the method comprising:
providing a substrate having a plurality of spaced parallel aluminum conductors on one side of said substrate;
forming a thin oxide layer on spaced pixel regions of each of said aluminum conductors to form a gate insulator over each of said spaced pixel regions;
forming a field-effect transistor (FET) on said thin oxide layer in each of said spaced pixel regions, said FET having a source terminal, a drain terminal, and a gate connected to the aluminum conductor on which said FET is formed; and
connecting each of said aluminum conductors directly to a CMOS controller adapted to supply gate control signals for said FETs.

2. The method of claim 1 in which said controller supplies a separate gate control signal for each of said aluminum conductors.

3. The method of claim 2 in which said FET has a threshold voltage that is CMOS compatible so that said FET can be driven directly by an output signal from the CMOS controller.

4. The method of claim 2 in which said FET has a threshold voltage of less than 3 volts.

5. The method of claim 2 in which said FET has a threshold voltage in the range from about 1 to about 2 volts.

6. The method of claim 1 in which said thin oxide layer has a thickness of less than one micron.

7. The method of claim 1 in which said thin oxide layer has a thickness of less than 0.5 micron.

8. An electrophoretic display comprising:
a substrate having a plurality of spaced parallel aluminum conductors on one side of said substrate;
a thin oxide layer on spaced pixel regions of each of said aluminum conductors to form a gate insulator over each of said spaced pixel regions;
a field-effect transistor (FET) on said thin oxide layer in each of said spaced pixel regions, said FET having a source terminal, a drain terminal, and a gate connected to the aluminum conductor on which said FET is formed; and
a CMOS controller adapted to supply gate control signals for said FETs directly to the gates of said FETs.

9. The electrophoretic display of claim 8 in which said controller supplies a separate gate control signal for each of said aluminum conductors.

10. The electrophoretic display of claim 9 in which said FET has a threshold voltage that is CMOS compatible so that said FET can be driven directly by an output signal from the CMOS controller.

11. The electrophoretic display of claim 9 in which said FET has a threshold voltage of less than 3 volts.

12. The electrophoretic display of claim 9 in which said FET has a threshold voltage in the range from about 1 to about 2 volts.

13. The electrophoretic display of claim 8 in which said thin oxide layer has a thickness of less than one micron.

14. The electrophoretic display of claim 8 in which said thin oxide layer has a thickness of less than 0.5 micron.

15. An electrophoretic display comprising:
a substrate having a plurality of spaced parallel conductors on one side of said substrate;
a thin insulating layer on spaced pixel regions of each of said conductors to form a gate insulator over each of said spaced pixel regions;
a field-effect transistor (FET) on said thin insulating layer in each of said spaced pixel regions, said FET having a source terminal, a drain terminal, and a gate connected to the conductor on which said FET is formed; and
a pixel electrode on each of said FETs;
an electrophoretic panel laminated onto said pixel electrodes;
a common electrode formed on said electrophoretic panel;
a pair of voltage sources coupled to said common electrode via a controllable switching module; and
a controller coupled to said switching module for controlling the magnitudes of the voltages supplied by said sources to said common electrode, said controller adapted to compare a desired voltage with the magnitude of the actual voltage supplied to said common electrode by at least one of said sources, and to adjust the magnitude of said actual voltage if needed to match said desired voltage.

16. The electrophoretic display of claim 15 which includes a field effect transistor for controlling said actual voltages of said voltage sources, and said controller is coupled to the gate of said field effect transistor and is adapted to supply said gate with a series of pulses for controlling said actual voltages.

17. The electrophoretic display of claim 16 in which said controller is adapted to control at least one of the number and width of said pulses.

18. An electrical control system for controlling the electrical voltage applied to each of multiple pixel electrodes on one side of an electrophoretic display, said system comprising:
multiple spaced aluminum column lines on a non-conductive substrate, each of said column lines having a layer of aluminum oxide on its surface,
multiple spaced row lines on said substrate and intersecting said column lines,
a plurality of field-effect transistors (FETs) spaced along each of said column lines with the gate of each FET connected to one of said column lines and the source or drain of each FET connected to one of said row lines,
a pixel electrode on each of said FETs,
an electrophoretic panel laminated onto said pixel electrodes, and
a common electrode formed on said electrophoretic panel.

19. A system for controlling an array of pixels in a display in which each pixel includes a field-effect transistor for controlling the absorption or reflection of light from a selected area of the display, said system comprising:
a substrate having a plurality of spaced elongated conductors arranged extending across the substrate, and multiple pixels formed along the length of each of said conductors, each pixel comprising
a thin dielectric layer on at least portions of said conductors corresponding to said pixels to form gate insulator layers for multiple field-effect transistors spaced along the length of each of said conductors, so that each of said conductors forms a gate terminal for each of said field-effect transistors spaced along the length of that conductor,
a pair of layers of n-type material on each of said dielectric layers, said layers of n-type material in each pair being spaced from each other to leave a portion of said dielectric material exposed between each pair of layers of n-type material,
a layer of p-type material on each of said dielectric layers in said exposed portion of said dielectric material between each pair of layers of n-type material, said p-type material overlapping portions of both of said layers in n-type material to form a pair of spaced p-n junctions on each of said dielectric layers,
a source terminal on one of said layers of n-type material in each of said pairs and an adjacent portion of said p-type material, and
a drain terminal on the other of said layers of n-type material in each of said pairs, and
a controller coupled to selected terminals of each of said field effect transistors and adapted to supply control signals to each of said field-effect transistors for controlling the emission or reflection of light from each pixel to produce a desired display.
